(19) United States
(12) Patent Application Publication
(10) Pub. No.: US 2026/0164548 A1
(43) Pub. Date: Jun. 11, 2026

(54) ELECTRONIC DEVICE AND MANUFACTURING METHOD THEREOF

(71) Applicant: InnoLux Corporation, Miao-Li County (TW)

(72) Inventors: Tzu-Kuan YANG, Miao-Li County (TW); Chia-Ping Tseng, Miao-Li County (TW); Chun-Chin Fan, Miao-Li County (TW); Chien-Ming Chen, Miao-Li County (TW)

(73) Assignee: InnoLux Corporation, Miao-Li County (TW)

(21) Appl. No.: 19/385,167

(22) Filed: Nov. 11, 2025

Related U.S. Application Data
(60) Provisional application No. 63/729,476, filed on Dec. 9, 2024.

(30) Foreign Application Priority Data
Jun. 27, 2025 (CN) 202510876397.9

(51) Int. Cl. H05K 1/02; H05K 1/11; H05K 1/18

(52) U.S. Cl. CPC H05K 1/0298; H05K 1/115; H05K 1/183

(57) ABSTRACT

The present disclosure provides an electronic device and a manufacturing method thereof. The manufacturing method includes providing a substrate including at least one through hole, forming a seed layer extending into the through hole on the substrate, forming an insulating layer extending into the through hole and exposing a portion of the seed layer in the through hole on the seed layer, and forming a conductor layer on the portion of the seed layer.

### CROSS REFERENCE TO RELATED APPLICATION

This application claims the benefit of U.S. Provisional Application No. 63/729,476, filed on Dec. 9, 2024. The content of the application is incorporated herein by reference.

### BACKGROUND OF THE DISCLOSURE

### 1. Field of the Disclosure

The present disclosure relates to an electronic device and a manufacturing method thereof and particularly to an electronic device and a manufacturing method thereof forming a conductor layer in a through hole of a substrate.

### 2. Description of the Prior Art

Recently, packing technology of electronic devices has been developed gradually toward 2.5D or 3D methods for packaging stacks. In order to package stacks, a through hole formed in an interposer or a substrate has been developed, and then, a conductor layer is formed in the through hole to provide electrical connection in a vertical direction. However, during forming the conductor layer, easier mass transfer and higher current density are at an orifice of the through hole, so that speed of forming the conductor layer at the orifice is faster than that of forming the conductor layer at a center of the through hole. For this reason, void or hole is generated at the center of the through hole, which affects signal transmission quality and reliability of the conductor layer.

### SUMMARY OF THE DISCLOSURE

One of objectives of the present disclosure is to provide an electronic device and a manufacturing method thereof to improve quality of a conductor layer in at least one through hole.

According to an embodiment of the present disclosure, a manufacturing method of an electronic device is provided. First, a substrate is provided, wherein the substrate includes at least one through hole. Then, a seed layer is formed on the substrate, wherein the seed layer extends into the through hole. Next, an insulating layer is formed on the seed layer, wherein a portion of the insulating layer extends into the through hole, and a portion of the seed layer in the through hole is exposed. Then, a conductor layer is formed on the portion of the seed layer.

According to an embodiment of the present disclosure, an electronic device is provided and includes a substrate, a seed layer, a conductor layer, and another conductor layer. The substrate includes at least one through hole. The seed layer is disposed on the substrate and extends into the through hole. The conductor layer is disposed on a portion of the seed layer in the through hole, and the another conductor layer is disposed on the seed layer and the conductor layer, wherein a grain size of the conductor layer is less than a grain size of the another conductor layer.

In the manufacturing method of the electronic device of the present disclosure, since the insulating layer having the opening is formed in the through hole before forming the conductor layer, the solid conductor layer may be formed at the center of the through hole to prevent another conductor layer from being closed too early at the orifice of the through holes, thereby reducing the probability of forming voids or holes in the through holes. Accordingly, the signal transmission quality and reliability of the conductive vias may be improved. In the electronic device of the present disclosure, the grain size of the conductor layer adjacent to the center of the through hole is less than that of the conductor layer away from the center of the through hole, which helps reduce total manufacturing time of the electronic device.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 and FIG. 2 schematically illustrate structures in different steps of a manufacturing method of an electronic device according to a first embodiment of the present disclosure.

FIG. 3 and FIG. 4 schematically illustrate structures in different steps of a manufacturing method of an electronic device according to a second embodiment of the present disclosure.

FIG. 5 schematically illustrates a cross-sectional view of an electronic device according to a third embodiment of the present disclosure.

FIG. 6 schematically illustrates a cross-sectional view of an electronic device according to a fourth embodiment of the present disclosure.

FIG. 7 schematically illustrates a cross-sectional view of an electronic device according to a fifth embodiment of the present disclosure.

FIG. 8 schematically illustrates a cross-sectional view of an electronic device according to a sixth embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure may be a simplified illustrations, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to...”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

In addition, when one element or layer is “connected to”another element or layer, it may be understood that the element or layer is directly connected to the another element or layer physically or electrically, and alternatively, the two may be physically or electrically connected through another element or layer (indirectly). On the contrary, when the element or layer is “directly connected to” another element or layer, it may be understood that there is no other element or layer between the two for physical or electrical connection. The term “connect” may include means of “directly connect” or “indirectly connect”. Besides, the term “electrically connect” or “couple” includes any direct or indirect means of electrical connection.

In the present disclosure, when one element is “disposed on” another element, the manufacturing procedure or sequence of forming the element and the another element is not limited thereto. In the present disclosure, when one element is “disposed on” another element, it may include one element is disposed on a sidewall of another element.

As disclosed herein, the terms “approximately”, “essentially”, “about”, or “substantially” generally mean within 10%, 5%, 3%, 2%, 1%, or 0.5% of the reported numerical value or range. The numbers given herein are approximated numbers, and that is, without specifically describing with the terms “approximately”, “essentially”, “about”, or “substantially”, it may still imply the meaning of the terms “approximately”, “essentially”, “about”, or “substantially”.

The term “between a number A and a number B” is interpreted as including the number A and the number B or as including at least one of the number A and the number B, and as including other numbers between the number A and the number B.

In the present disclosure, the depth, thickness, length, width, distance, and diameter may be measured by using an optical microscope (OM), a scanning electron microscope (SEM) or other approaches, but not limited thereto.

In the present disclosure, the definition of roughness may be a peak-to-valley distance of 0.15 micrometers (μm) to 1 μm of surface undulations observed by a SEM. The measurement of determining the roughness may include using a SEM or a transmission electron microscope (TEM), etc. to observe peaks and valleys of surface undulations in a proper magnification factor, and comparing the surface undulations by taking a unit length (e.g., 10 μm) to obtain its roughness range. Here, the term “proper magnification factor” means at least one surface may be observed a roughness (Rz) or an averaged roughness (Ra) with at least 10 peaks in the visual field in this magnification factor.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, include a display device, a light emitting device, a sensing device, an antenna device, a touch device, a tiled device, a package device, or other suitable electronic devices, but not limited thereto. The electronic device may, for example, be a bendable, stretchable, foldable, rollable, and/or flexible electronic device, but not limited thereto. The display device may, for example, be applied to laptop, public display, tiled display, car display, touch display, TV, monitor, smartphone, tablet, light source module, lighting equipment, military equipment, or electronic device applied to the aforementioned products, but not limited thereto. The sensing device may, for example, be a sensing device used for detecting variation in capacitances, light, heat, or ultrasound, but not limited thereto. The sensing device may, for example, include a bio-sensor, a touch sensor, a fingerprint sensor, other suitable sensors, or any combination of the aforementioned sensors. The display device may, for example, include liquid crystal molecules, a light emitting diode, a fluorescent material, a phosphor material, other suitable display media, or a combination of the aforementioned display media, but not limited thereto. The light emitting diode may, for example, include an organic light emitting diode (OLED), a mini light emitting diode (mini LED), a micro light emitting diode (micro LED), or a quantum dot light emitting diode (e.g., QLED or QDLED), but not limited thereto. The antenna device may include liquid crystal antenna, varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems, such as a driving system, a control system, a light source system, a shelf system, etc. The electronic device may include electronic units, in which the electronic units may include a passive element and an active element, and for example, include a capacitor, a resistor, an inductor, a diode, a transistor, a sensor, etc. It is noted that the electronic device of the present disclosure may be any combination of the above-mentioned devices, but not limited thereto. The manufacturing method of the package device of the present disclosure may, for example, be applied to a wafer-level package (WLP) process or a panel-level package (PLP) process, wherein the WLP or the PLP may include a chip-first process or a chip-last process, but not limited thereto. The electronic device of the present disclosure may, for example, be applied to a package device, a power module, a display device, a light emitting device, a backlight device, an antenna device, a sensing device, or a tiled device, but not limited thereto. The electronic device may include high bandwidth memory (HBM) package, system on a chip (SoC), system in a package (SiP), antenna in package (AiP), co-packaged optics (CPO), or any combination of the aforementioned devices, but not limited thereto.

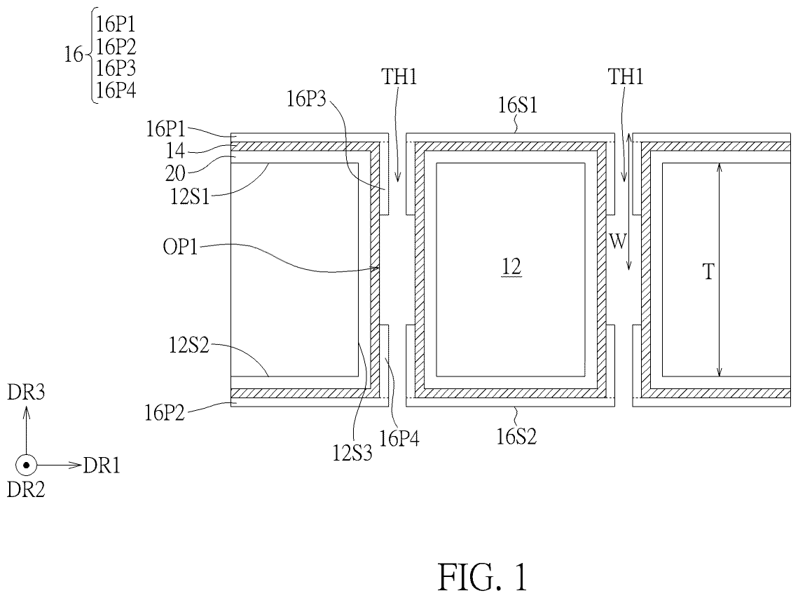

The following drawings show a direction DR1, a direction DR2, and a direction DR3. The direction DR3 may be a normal direction or a top view direction of the electronic device, and as shown in FIG. 1, the direction DR3 may be perpendicular to a first surface 12S1 of a substrate 12. The direction DR1 and the direction DR2 each may be a horizontal direction and may be perpendicular to the direction DR3. As shown in FIG. 1, the direction DR1 and the direction DR2 may be parallel to the first surface 12S1 of the substrate 12, and the direction DR1 and the direction DR2 may be perpendicular to each other. The following contents may describe the spatial relations of structures based on the direction DR1, the direction DR2, and the direction DR3 in the following drawings.

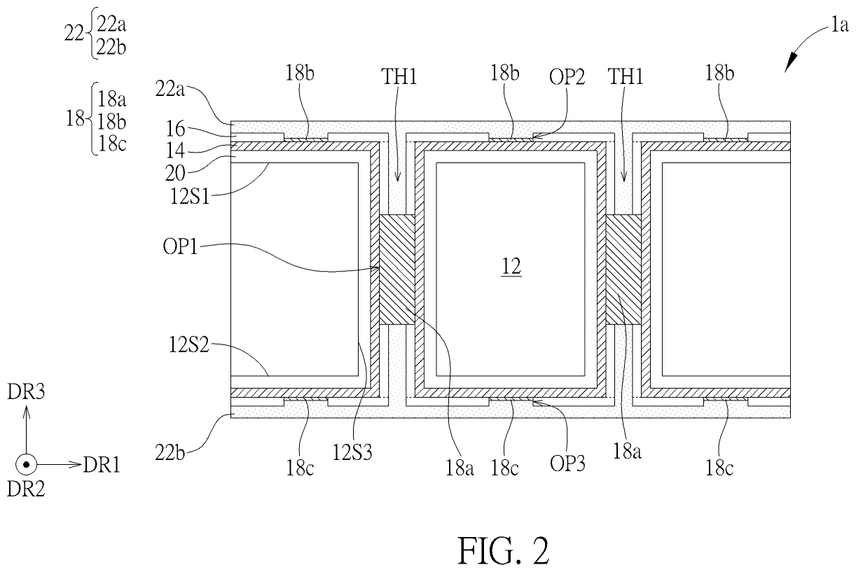

Refer to FIG. 1 and FIG. 2. FIG. 1 and FIG. 2 schematically illustrate structures in different steps of a manufacturing method of an electronic device according to a first embodiment of the present disclosure, wherein FIG. 2 schematically illustrates a cross-sectional view of the electronic device according to the first embodiment of the present disclosure. As shown in FIG. 1 and FIG. 2, the manufacturing method of the electronic device 1a may include at least the following steps: providing a substrate 12 with at least one through hole TH1; forming a seed layer 14 on the substrate 12; forming an insulating layer 16 on the seed layer 14; and forming a conductor layer 18 on the seed layer 14, wherein a portion of the insulating layer 16 extends into the through hole TH1, and a portion of the seed layer 14 in the through hole TH1 is exposed. The conductor layer 18 is formed on exposed portion of the seed layer 14. The above manufacturing method may help reduce the possibility of voids or holes occurring in conductive vias formed in the following step, so as to improve signal transmission quality and reliability of the conductive vias. The manufacturing method of the present disclosure is not limited to the above steps, and another step may be performed before, after, or during any of the above steps. It should be noted that in the figures of the present disclosure, portions of the substrate 12 on two sides of the through hole TH1 are not separated from each other and may be connected to each other in different cross-sectional views.

The manufacturing method of the electronic device 1a of this embodiment is further detailed in the following contents with FIG. 1 to FIG. 2. As shown in FIG. 1, the step of providing the substrate 12 may include performing a patterning process on the substrate 12 to form at least one through hole TH1 in the substrate 12, wherein the through hole TH1 penetrates through the substrate 12. Taking the substrate 12 including glass as an example, the patterning process may include, for example, performing a modification process on a portion of the substrate 12 to be formed as the through hole TH1 and performing an etching process, photolithography and etching processes, or other suitable processes on the modified portion of the substrate 12. The modification process may include, for example, a laser irradiation, and the etching process may include, for example, a wet etching process using an etching solution, such that different portions of the substrate 12 have obvious etching selectivity ratio with respect to the etching solution, and the through hole TH1 may be formed. In other words, the substrate 12 may allow laser to penetrate therethrough, but not limited thereto. The etching process for forming the through hole TH1 in the present disclosure may be performed, for example, on the first surface 12S1 or the second surface 12S2 of the substrate 12, or on both the first surface 12S1 and the second surface 12S2 of the substrate 12 at the same time to form the through hole TH1, but not limited thereto. The “modification” in the present disclosure refers to perform an adjustment of bond strength on a local region of the substrate 12 by laser or other suitable methods, or weaken structural strength of the local region. According to some embodiments, the etching solution may include acidic or alkaline liquid, wherein the acidic etching solution includes hydrofluoric acid, and the alkaline etching solution includes sodium hydroxide, but not limited thereto. According to some embodiments, average roughness of the through hole TH1 may be from 0.1 μm to 1 μm to improve adhesion of the substrate 12 with subsequent layer, but not limited thereto. A thickness of the substrate 12 on the direction DR3 may be greater than or equal to 0.1 millimeters (mm), such as 0.2 mm, 0.8 mm, 1.2 mm, or 1.6 mm, but not limited thereto. In some embodiments, an aspect ratio of the through hole TH1 may, for example, be greater than or equal to 8, 10, or 15, but not limited thereto. A coefficient of thermal expansion of the substrate 12 may be greater than or equal to 1 ppm/° C. and less than or equal to 10 ppm/° C.

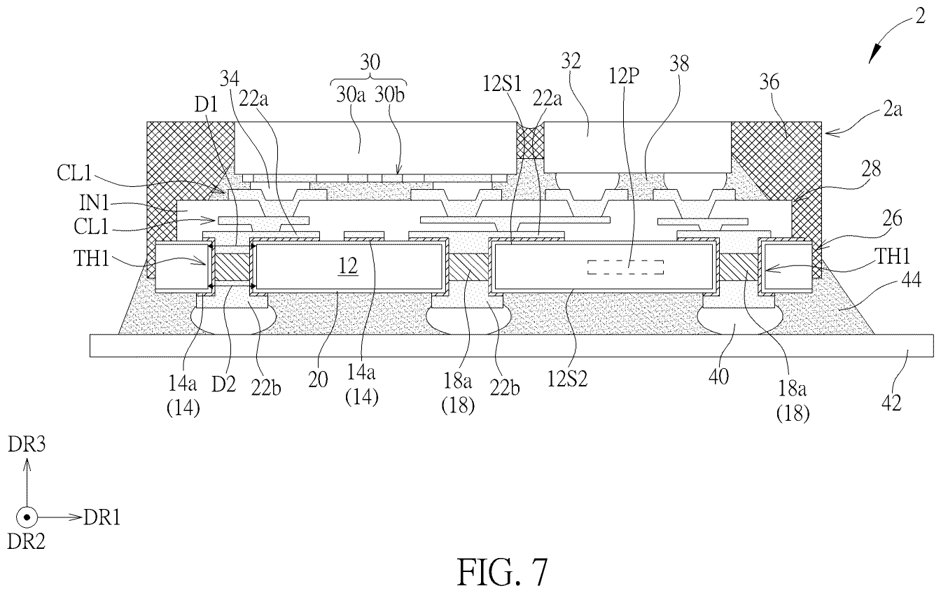

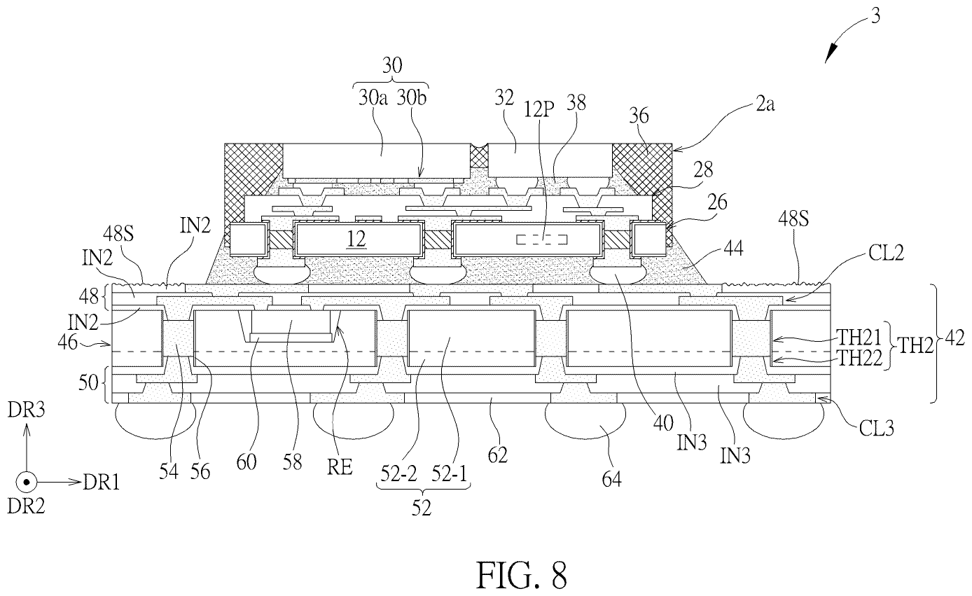

In this embodiment, the number of through holes TH1 may be multiple, but not limited thereto. In some embodiments, a cross-sectional shape of the through hole TH1 may be rectangular, trapezoidal, inverted trapezoid, dumbbell, hourglass, or other suitable shapes. In some embodiments, the substrate 12 may be, for example, a single-layer or multilayer structure. A transmittance of the substrate 12 with respect to light (e.g. white light) may be, for example, greater than 80%. The substrate 12 may include, for example, a glass substrate, a transparent material containing silicon, an optical layer, an acrylic plate, other transparent materials or a combination thereof, so as to have certain rigidity and insulation. In other words, rigidity of the substrate 12 may be greater than that of a circuit structure formed in subsequent steps, and for example, the rigidity of the substrate 12 is greater than that of an insulating layer of the circuit structure (e.g., an insulating layer IN1 of the circuit structure 28 shown in FIG. 7 or FIG. 8), so that the substrate 12 may mitigate warping of the circuit structure, but not limited thereto. Alternatively, a dielectric loss (Df) of the substrate 12 is less than that of the insulating layer of the circuit structure, so that electrical characteristics of the electronic device 1a may be improved when the substrate 12 is used to carry the circuit structure, but not limited thereto.

In this embodiment, after the step of providing the substrate 12 (or before the step of forming the seed layer 14), a buffer layer 20 may be selectively formed on the exposed surface of the substrate 12 (e.g., the first surface 12S1, the second surface 12S2 and sidewalls 12S3 of the through holes TH1 of the substrate 12). The buffer layer 20 may, for example, be used to provide cushioning and protection for the substrate 12. The buffer layer 20 may cover at least corners of the substrate 12 to reduce break of the corners of the substrate 12, for example, cover the corners formed by the sidewalls 12S3 of the through holes TH1 and the first surface 12S1 or the second surface 12S2. In this embodiment, the buffer layer 20 may, for example, cover the first surface 12S1, the second surface 12S2, and the sidewalls 12S3 of the through holes TH1 of the substrate 12. The buffer layer 20 may also be used as an adhesion promoter layer or other suitable layers, for example, to improve the adhesion between the substrate 12 and the seed layer 14. The method of forming the buffer layer 20 may include a deposition process, a coating process with a laser drilling or etching process, or other suitable processes. The deposition process may include, for example, an atomic layer deposition process, a physical deposition process, or a chemical deposition process. A thickness of the buffer layer 20 may be, for example, greater than or equal to 0.25 μm. In some embodiments, there may be no buffer layer 20 formed after the step of providing the substrate 12.

The material of buffer layer 20 may include, for example, an inorganic material or an organic material, wherein the inorganic material of the buffer layer 20 may include, for example, metal, metal alloy, oxide, nitride, suitable ceramic material, other suitable inorganic materials, or a combination thereof, and the organic material of the buffer layer 20 may include, for example, polyimide (PI), poly-p-xylylene (Parylene), benzocyclobutene (BCB), epoxy, polycarbonate (PC), polyethylene terephthalate (PET), polyethylene naphthalate (PEN), polymer or other suitable materials. The buffer layer 20 may be, for example, a single layer or multilayer structure. When the buffer layer 20 is the multilayer structure, the buffer layer 20 may include a structure of an inorganic material layer, an organic material layer, and an inorganic material layer stacked in sequence, a structure of an organic material layer, an inorganic material layer, and an organic material layer stacked in sequence, a structure of an organic material layer, an organic material layer, and an organic material layer stacked in sequence, or other suitable structures. The toughness of the buffer layer 20 may be greater than or equal to 0.1 kilojoules per square meter (kJ/m²) and less than or equal to 100 kJ/m² (i.e., 0.1 kJ/m²≤toughness of the buffer layer≤100 kJ/m²). In the present disclosure, the toughness of a layer may be obtained by integrating an area under a stress-strain curve, and the stress-strain curve may be obtained by performing a tensile test on the layer using a universal testing machine (UTM). A dielectric loss of the buffer layer 20 may be less than that of the substrate 12. For example, the dielectric loss of the buffer layer 20 may be less than 0.1 while the operating frequency of the buffer layer is greater than or equal to 10 MHz, thereby reducing the impact on signal transmission and particularly reducing the impact on the transmission of high-frequency signals.

After the step of forming the buffer layer 20 (or the step of providing the substrate 12), the seed layer 14 is formed on the buffer layer 20 (or the substrate 12), and the seed layer 14 extends into the through hole TH1 to facilitate the subsequent step of forming the conductor layer 18. The seed layer 14 may, for example, cover the buffer layer 20 located on the first surface 12S1, the second surface 12S2, and the sidewalls 12S3 of the through holes TH1 of the substrate 12, but not limited thereto. In some embodiments, when there is no buffer layer 20 formed on the substrate 12, the seed layer 14 may be formed directly on the first surface 12S1, the second surface 12S2, and the sidewalls 12S3 of the through holes TH1 of the substrate 12, for example. The thickness of the seed layer 14 may be, for example, greater than or equal to 0.1 μm. The thickness of the seed layer 14 referred to in the present disclosure may be the maximum thickness, for example.

The method of forming the seed layer 14 may include, for example, electroless plating, sputtering, evaporation, atomic layer deposition processes, chemical vapor deposition (CVD) processes, other suitable processes, or a combination thereof. The seed layer 14 may include, for example, copper (Cu), titanium (Ti), titanium nitride (TiN), other suitable metals, or an alloy or a combination thereof. It should be noted that the seed layer 14 may be formed from the first surface 12S1 or the second surface 12S2 of the substrate 12, or from the first surface 12S1 and the second surface 12S2 of the substrate 12 at the same time. The seed layer 14 may have electrically conductive ability. The seed layer 14 may improve quality of conductor layer subsequently formed or provide adhesion between the conductor layer and the substrate, but not limited thereto.

After the step of forming the seed layer 14, an insulating layer 16 is formed on the seed layer 14, and portions of the insulating layer 16 extends into the through holes TH1, in which portions of the seed layer 14 in the through holes TH1 are exposed. Specifically, the insulating layer 16 may be formed on the first surface 12S1 and the second surface 12S2 and portions of the sidewalls 12S3 of the through holes TH1 of the substrate 12, and the insulating layer 16 may have a plurality of openings OP1 respectively located in the corresponding through holes TH1 and exposing the portions of the seed layer 14. In other words, the insulating layer 16 may include a portion 16P1 located on the first surface 12S1 of the substrate 12, a portion 16P2 located on the second surface 12S2 of the substrate 12, a plurality of portions 16P3 respectively located in the through holes TH1 and connected to the portion 16P1, and a plurality of portions 16P4 respectively located in the through holes TH1 and connected to the portion 16P2, wherein there may be an opening OP1 between one of the portions 16P3 and one of the portions 16P4 located in the same one of the through holes TH1. A thickness of the insulating layer 16 may be, for example, greater than or equal to 0.25 μm, that is, in any portion of the insulating layer, the thickness of the insulating layer 16 may be, for example, greater than or equal to 0.25 μm and less than or equal to 10 μm to avoid affecting subsequent processes.

In one embodiment, there is a distance W in the direction DR3 between a center of one of the openings OP1 and a surface (e.g., an upper surface 16S1 or a lower surface 16S2) of the insulating layer 16 outside the through holes TH1, and the distance W may be, for example, greater than or equal to a quarter of the thickness T of the substrate 12 and less than or equal to a half of the thickness T of the substrate 12 (i.e., T/4≤distance W≤T/2). Alternatively, a length of the portion 16P3 or the portion 16P4 of the insulating layer 16 extending into the through hole TH1 in the direction DR3 may be greater than or equal to 0.05 times the distance W and less than or equal to 0.8 times the distance W. The above structure may help form the solid conductor layer 18 at the centers of the through holes TH1 in subsequent processes, thereby reducing the probability of forming voids or holes at the centers of the through holes TH1.

The insulating layer 16 may include, for example, organic or inorganic material, wherein the inorganic material of the insulating layer 16 may include, for example, oxide, nitride, suitable ceramic materials, other suitable inorganic insulating materials or a combination thereof, and the organic material of the insulating layer 16 may include, for example, positive or negative photoresist material, but not limited thereto. The method of forming the insulating layer 16 may include, for example, coating, atomic layer deposition, physical deposition process, chemical deposition process, or other suitable processes.

In the embodiment of FIG. 2, after the step of forming the insulating layer 16, the insulating layer 16 may be optionally patterned to expose at least a portion of the seed layer 14 located outside the through holes TH1 of the substrate 12. In other words, the insulating layer 16 may further have at least one opening OP2 and/or at least one opening OP3 located outside the through holes TH1, wherein the opening OP2 exposes another portion of the seed layer 14 on the first surface of the substrate 12, and the opening OP3 exposes another portion of the seed layer 14 on the second surface 12S2 of the substrate 12. In FIG. 2, the number of the openings OP2 and the openings OP3 may be multiple, and for example, expose a plurality of portions of the seed layer 14, but not limited thereto. The method of patterning the insulating layer 16 may include, for example, photolithography and etching processes or other suitable processes. In some embodiments, the manufacturing method of the electronic device 1a may not include the step of patterning the insulating layer 16. In some embodiments, the insulating layer 16 may be used to reduce stress resulted from the mismatch of coefficients of thermal expansion, but not limited thereto.

Then, the conductor layer 18 is formed on the exposed portions of the seed layer 14. The method of forming the conductor layer 18 may include, for example, electroplating, electroless plating or other suitable processes. The conductor layer 18 may include, for example, Cu or other suitable metal materials. It should be noted that when the conductor layer 18 is formed by the electroplating process with an electroplating solution, the electroplating solution may easily flow into the through holes TH1 with the buffer layer 20, the seed layer 14, and the insulating layer 16 formed therein, and then the conductor layer 18 may be formed from the exposed portions of the seed layer 14 with conductive characteristic. In this case, forming the openings OP2 and/or the openings OP3 in the insulating layer 16 help form the conductor layer 18 on local regions of the substrate 12 and/or help adjust the number and areas of the exposed portions of the seed layer 14 to improve uniformity of current density in the electroplating process, thereby increasing the quality of the conductor layer 18. The uniformity of current density may include, for example, morphology of grain formation, uniformity of the electric field in the electroplating solution, uniformity of the thickness of the conductor layer 18, or growth rate of the electroplating process. The forming rate of the conductor layer 18 may be faster than that of the seed layer 14, for example. A grain size of the seed layer 14 may be, for example, less than that of the conductor layer 18.

In the embodiment of FIG. 2, the conductor layer 18 may include a plurality of bridging portions 18a, a plurality of pattern portions 18b, and a plurality of pattern portions 18c, wherein the bridging portions 18a may correspond to the openings OP1, respectively, and the pattern portions 18b may respectively correspond to other portions of the seed layer 14 exposed by the openings OP2, and the pattern portions 18c may respectively correspond to other portions of the seed layer 14 exposed by the openings OP3, but not limited thereto. The numbers of the pattern portions 18b and the pattern portions 18c may be determined according to the numbers of the openings OP2 and the openings OP3, but not limited to the number shown in FIG. 2. The spaces between the portions of the seed layer 14 exposed by the openings OP1 may be respectively filled up with the bridging portions 18a. In other words, the bridging portions 18a may have no voids or holes, so that in a cross-sectional direction (e.g., the direction DR1), a width of one of the bridging portion 18a may be the same as a distance between two portions of the seed layer 14 in the same one of the through holes TH1, thereby reducing the probability of forming voids or holes at the centers of the through holes TH1. In some embodiments, the openings OP2 or the openings OP3 may correspond to positions of traces that are predetermined to be formed, that is, the formed pattern portions 18b or the pattern portions 18c may be used as portions of traces of circuit structure formed in subsequent steps, but not limited thereto. An element A corresponding to another element B in the present disclosure means that in a certain direction, the elements A and B may overlap each other or the elements A and B may be in direct contact with each other.

After the conductor layer 18 is formed, a conductor layer 22 is formed on the conductor layer 18 and the insulating layer 16 to form the electronic device 1a of this embodiment. It is worth noting that remaining spaces in the through holes TH1 may be filled up with the conductor layer 22 to form conductive vias without voids or holes in the through holes TH1, so as to improve signal transmission quality and reliability of the conductive vias.

The method of forming the conductor layer 22 may include, for example, electroplating or other suitable processes. The conductor layer 22 may include, for example, Cu or other suitable metal materials. For example, the conductor layer 22 may be formed from exposed portions of the conductor layer 18. When both the conductor layer 18 and the conductor layer 22 are formed by the electroplating processes, parameters of the electroplating process for forming the conductor layer 22 may be different from parameters of the electroplating process for forming the conductor layer 18, for example, the electroplating processes have different current densities, different durations, different ion concentrations of the electroplating solutions, and/or other different suitable parameters. For example, electroplating rate in the step of forming the conductor layer 22 may be greater than that in the step of forming the conductor layer 18 to reduce total manufacturing time of the electronic device 1a. In this case, the grain size of the conductor layer 18 may be, for example, less than that of the conductor layer 22. In some embodiments, the electroplating process for forming the conductor layer 22 may be performed with a mask layer. For example, before the electroplating process, a photoresist pattern may be formed on the insulating layer 16 outside the through holes TH1 as a mask, so that the pattern portions 18b may be formed at the predetermined positions or with predetermined patterns in the electroplating process.

In this embodiment, the openings OP2 and the openings OP3 of the insulating layer 16 may be filled up with the conductor layer 22, and the conductor layer 22 may extend to the insulating layer 16 outside the through holes TH1, but not limited thereto. Specifically, the conductor layer 22 may include at least one conductive pattern 22a and at least one conductive pattern 22b, wherein the conductive pattern 22a may be disposed on the insulating layer 16 located on the first surface 12S1 of the substrate 12 and extend into portion of the through holes TH1 adjacent to the first surface 12S1, and the conductive pattern 22b may be disposed on the insulating layer 16 located on the second surface 12S2 of the substrate 12 and extend into portion of the through holes TH1 adjacent to the second surface 12S2. One of the bridging portions 18a of the conductor layer 18 in one of the through holes TH1, portions of the conductive pattern 22a and the conductive pattern 22b in the through hole TH1, and the portion of the seed layer 14 in the through hole TH1 may form the conductive via used to electrically connect an element on the first surface 12S1 of the substrate 12 to another element on the second surface 12S2 of the substrate 12.

In FIG. 2, the numbers of the conductive pattern 22a and the conductive pattern 22b are respectively one as an example, but not limited thereto. In some embodiments, the number of the conductive pattern 22a may be multiple, and/or the number of the conductive pattern 22b may also be multiple. In this case, the conductive patterns 22a may be separated from each other, and the conductive patterns 22b may be separated from each other. In some embodiments, the electroplating process for forming the conductor layer 22 may be performed with the mask layer, so that at least one of the conductive patterns 22a and/or at least one of the conductive patterns 22b may not extend into the through holes TH1, but not limited thereto. In this case, the mask layer may be removed after the conductor layer 22 is formed. In some embodiments, when the conductor layer 22 includes a plurality of conductive patterns 22a and a plurality of conductive patterns 22b, the manufacturing method may further include removing portion of the insulating layer 16 that is not covered by the conductor layer 22 and portion of the seed layer 14 below the portion of the insulating layer 16 after the mask layer is removed, but not limited thereto.

It should be noted that since the solid bridging portions 18a are formed in the through holes TH1 before forming the conductor layer 22, it may prevent the conductor layer 22 from being closed too early at the orifice of the through holes TH1 during forming the conductor layer 22, thereby reducing the probability of forming voids or holes in the through holes TH1. Accordingly, the signal transmission quality and reliability of the conductive vias may be improved.

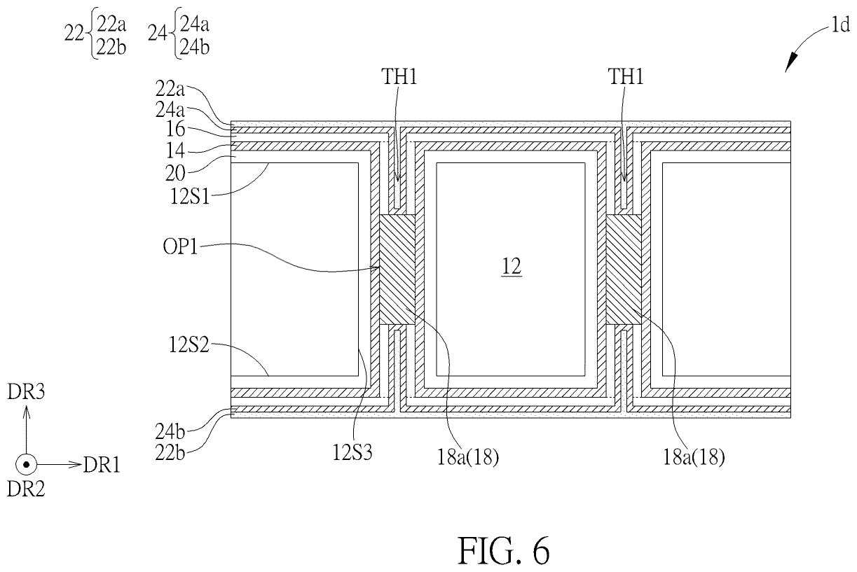

In some embodiments, the manufacturing method of FIG. 2 may further optionally remove the insulating layer 16 between the step of forming the conductor layer 18 and the step of forming the conductor layer 22, so that in addition to the exposed conductor layer 18, the seed layer 14 may also be exposed, thereby increasing the forming rate of the conductor layer 22 to shorten the total manufacturing time of the electronic device 1a. In some embodiments, the manufacturing method shown in FIG. 2 may further optionally include forming another seed layer (e.g., a seed layer 24 of FIG. 6) between the step of forming the conductor layer 18 and the step of forming the conductor layer 22 to help reduce the total manufacturing time of the electronic device 1a.

As shown in FIG. 2, through the above manufacturing method, the electronic device 1a formed in this embodiment may at least include the substrate 12, the seed layer 14, the conductor layer 18, and the conductor layer 22. The substrate 12 has at least one of the through holes TH1. The seed layer 14 is disposed on the substrate 12 and extends to the through hole TH1. The conductor layer 18 is disposed on portion of the seed layer 14 in the through hole TH1, and the conductor layer 22 is disposed on the seed layer 14 and the conductor layer 18. Moreover, the grain size of the conductor layer 18 may be less than that of the conductor layer 22. In some embodiments, the grain size of the seed layer 14 may be, for example, less than that of the conductor layer 18.

In this embodiment, the electronic device 1a may further include the insulating layer 16 disposed between the seed layer 14 and the conductor layer 22, wherein the insulating layer 16 extends into the through holes TH1 and has the openings OP1 located in the through holes TH1, and the openings OP1 respectively expose corresponding portions of the seed layer 14. In this embodiment, the insulating layer 16 may further have the openings OP2 located on the first surface 12S1 outside the through holes TH1, and the openings OP2 respectively expose portions of the seed layer 14. In some embodiments, the insulating layer 16 may further have the openings OP3 located on the second surface 12S2 outside the through holes TH1, and the openings OP3 respectively expose portions of the seed layer 14.

In FIG. 2, the conductor layer 18 may include the bridging portions 18a and the pattern portions 18b, wherein the bridging portions 18a cover the portions of the seed layer 14 exposed by the openings OP1, and the pattern portions 18b cover other portions of the seed layer 14 exposed by the openings OP2. In some embodiments, the conductor layer 18 may further include the pattern portions 18c located on the second surface 12S2 outside the through holes TH1, and the openings OP3 respectively expose other portions of the seed layer 14. In addition, the electronic device 1a may optionally further include the buffer layer 20 disposed between the substrate 12 and the seed layer 14, but not limited thereto.

The electronic device and the manufacturing method thereof are not limited to the above-mentioned embodiments and may have other embodiments. To simplify description, different embodiments in the following contents will use the same notations to the same elements as the first embodiment. To clearly illustrate different embodiments, differences between different embodiments will be described below, and repeated parts will not be detailed redundantly.

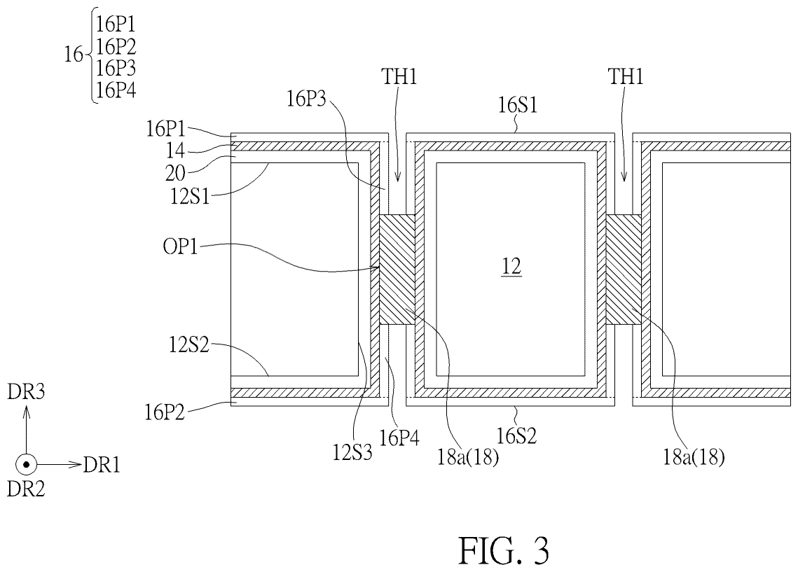

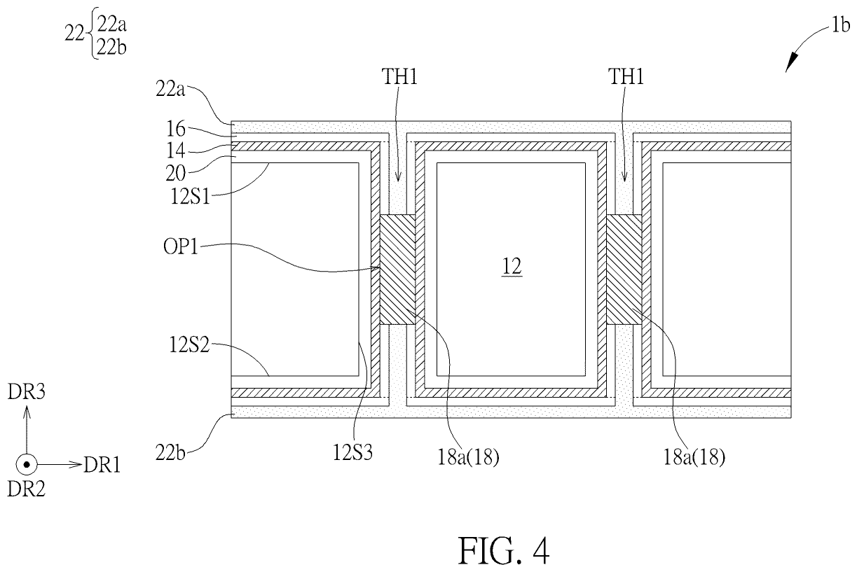

Refer to FIG. 3 and FIG. 4. FIG. 3 and FIG. 4 schematically illustrate structures in different steps of a manufacturing method of an electronic device according to a second embodiment of the present disclosure, wherein FIG. 2 schematically illustrates a cross-sectional view of the electronic device according to the second embodiment of the present disclosure. As shown in FIG. 3, the manufacturing method of the electronic device 1b in this embodiment differs from the manufacturing method of the above embodiment in that the manufacturing method of the electronic device 1b does not include the step of patterning the insulating layer 16 after the insulating layer 16 is formed but directly performs the step of forming the conductor layer 18. In other words, the insulating layer 16 of this embodiment does not include the openings OP2 and the openings OP3, and the conductor layer 18 may not include the pattern portions 18b and the pattern portions 18c shown in FIG. 2. The conductor layer 18 may include the bridging portions 18a corresponding to the openings OP1 and filling the spaces between the portions of the seed layer 14 exposed by the openings OP1. The method of forming the conductor layer 18 may be identical or similar to the above embodiment, and above contents may be referenced. In addition, the manufacturing method of the electronic device 1b of this embodiment is identical to the manufacturing method of the above embodiment in the step of forming the insulating layer 16 and other steps before it, so FIG. 1 and the above contents may be referenced, and it will not be repeated herein.

As shown in FIG. 4, after the conductor layer 18 is formed, the conductor layer 22 is formed on the conductor layer 18 and the insulating layer 16 to form the electronic device 1b of this embodiment. In this embodiment, the method of forming the conductor layer 22 and the material of the conductor layer 22 may be identical or similar to the above embodiment, so the above contents may be referenced. Further, by adjusting the electroplating parameters of the electroplating process, the conductor layer 22 may be formed from the exposed conductor layer 18 and formed on the insulating layer 16. Accordingly, the conductor layer 22 may fill up the remaining spaces in the through holes TH1 and extend onto the insulating layer 16 located outside the through holes TH1. Other parts of the electronic device 1b and the manufacturing method thereof in this embodiment may be identical to that of the above embodiment, so the above contents may be referenced, and they will not be repeated herein.

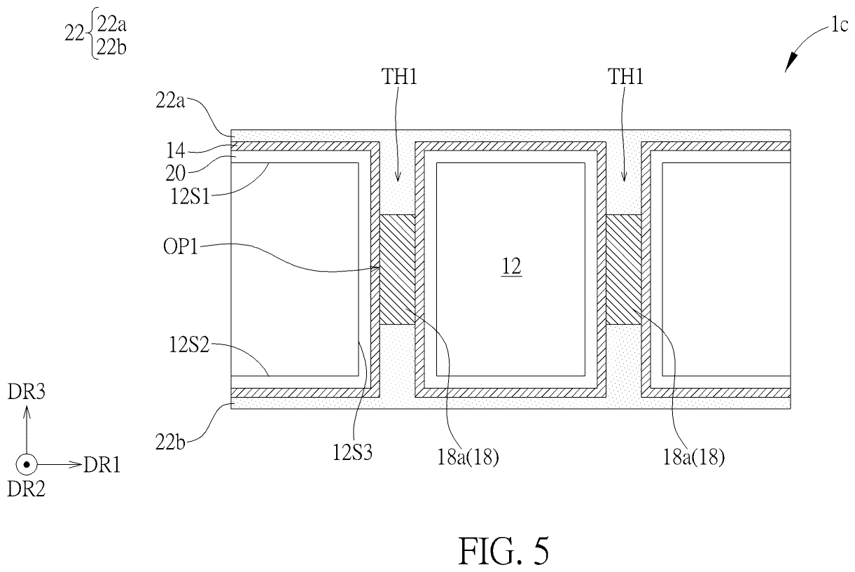

Refer to FIG. 5, which schematically illustrates a cross-sectional view of an electronic device according to a third embodiment of the present disclosure. As shown in FIG. 5, the manufacturing method of the electronic device 1c differs from the manufacturing method of FIG. 3 and FIG. 4 in that the manufacturing method of the electronic device 1c may include the step of removing the insulating layer 16 to expose the seed layer 14 after the conductor layer 18 is formed, so as to shorten the total manufacturing time of the electronic device 1c. The step of removing the insulating layer 16 may include, for example, an etching process for an insulating material or other suitable processes. Then, the conductor layer 22 is formed on the conductor layer 18 and the seed layer 14 to form the electronic device 1c of this embodiment. In this case, the conductor layer 22 may directly contact the seed layer 14. In this embodiment, the manufacturing method of the electronic device 1c may be identical to the manufacturing method of the above embodiment in the steps before and after removing the insulating layer 16, so FIG. 3 and the above contents may be referenced, and they will not be repeated herein. In some embodiments, an etching process, such as a descum process, may be further performed between the step of removing the insulating layer 16 and the step of forming the conductor layer 18 to help remove the insulating layer 16 located at the corners, thereby improving the quality and efficiency of forming the conductor layer 22. In some embodiments, when the conductor layer 22 includes a plurality of conductive patterns 22a and a plurality of conductive patterns 22b, the manufacturing method may further include removing the portion of the seed layer 14 that is not covered by the conductor layer 22 after the mask layer is removed, but not limited thereto. Other parts of the electronic device 1c and the manufacturing method thereof in this embodiment may be the same as the above embodiment, so the above contents may be referenced, and they will not be repeated herein.

Refer to FIG. 6, which schematically illustrates a cross-sectional view of an electronic device according to a fourth embodiment of the present disclosure. As shown in FIG. 6, the manufacturing method of the electronic device 1d differs from the manufacturing method of FIG. 3 and FIG. 4 in that the manufacturing method of the electronic device 1d may further include forming a seed layer 24 on the insulating layer 16 and the conductor layer 18 after forming the conductor layer 18. In this embodiment, the seed layer 24 may include a first portion 24a and a second portion 24b, wherein the first potion 24a is disposed on the first surface 12S1 of the substrate 12 and extends into the through holes TH1, and the second portion 24b is disposed on the second surface 12S2 of the substrate 12 and extends into the through holes TH1. Then, the conductor layer 22 is formed on the seed layer 24 to form the electronic device 1d of this embodiment. In other words, the seed layer 24 may be disposed between the insulating layer 16 and the conductor layer 22. This architecture may help increase the forming rate of the conductor layer 22, thereby shortening the total manufacturing time of electronic devices 1d. In this embodiment, the manufacturing method of the electronic device 1d may be identical to the manufacturing method of FIG. 3 and FIG. 4 in the steps before and after forming the seed layer 24, so FIG. 3 and the above contents may be referenced, and it will not be repeated herein. In some embodiments, when the conductor layer 22 includes a plurality of conductive patterns 22a and a plurality of conductive patterns 22b, the manufacturing method may further include removing portions of the seed layer 24, the insulating layer 16, and the seed layer 14 that are not covered by the conductor layer 22 after the mask layer is removed, but not limited thereto. Other parts of the electronic device 1d and the manufacturing method thereof in this embodiment may be the same as the above embodiment, so the above contents may be referenced, and they will not be repeated herein.

Refer to FIG. 7, which schematically illustrates a cross-sectional view of an electronic device according to a fifth embodiment of the present disclosure. As shown in FIG. 7, the electronic device 2 of this embodiment may include a core substrate 26, a circuit structure 28, and at least one electronic unit (e.g., an electronic unit 30 and an electronic unit 32), wherein the circuit structure 28 is disposed on the core substrate 26, and the electronic unit is located on the circuit structure 28. In this embodiment, the core substrate 26 may be formed, for example, using the electronic device 1c of FIG. 5 or of the electronic device 1c of FIG. 5. For example, when the seed layer 14 in the electronic device 1c of FIG. 5 has not yet been patterned, the conductor layer 22 may be further used as a mask to remove the seed layer 14 that is not covered by the conductor layer 22, so as to form the core substrate 26. In FIG. 7, the core substrate 26 may include, for example, the substrate 12, the buffer layer 20, the seed layer 14, the conductor layer 18, and the conductor layer 22, wherein the substrate 12 has at least one through hole TH1. The seed layer 14 may, for example, include a plurality of seed patterns 14a, wherein at least one of the seed patterns 14a may be disposed on the substrate 12 and extend into the through hole TH1, and at least another of the seed patterns 14a may be disposed on the first surface 12S1 or the second surface 12S2 of the substrate 12 and not extend into the through hole TH1. Taking a plurality of the through holes TH1 as an example, the conductor layer 18 may include a plurality of bridging portions 18a respectively disposed in the corresponding through holes TH1. The conductor layer 22 may include a plurality of conductive pattern 22a and a plurality of conductive pattern 22b, wherein the conductive patterns 22a are disposed between the circuit structure 28 and the substrate 12, and the conductive patterns 22b are disposed on a side of the circuit structure 28 opposite to the substrate 12. At least one of the conductive patterns 22a may be disposed on the first surface 12S1 of the substrate 12 and extend into one of the through holes TH1, and at least one of the conductive patterns 22b may be disposed on the second surface 12S2 of the substrate 12 and extend into one of the through holes TH1. In this embodiment, one of the conductive patterns 22a may be, for example, used to be electrically connected to the circuit structure 28 or used as a trace of the circuit structure 28. One of the conductive patterns 22b may be used as a bonding pad used to be bonded with other elements, for example. In this case, at least one of the conductive patterns 22a may be disposed on the first surface 12S1 of the substrate 12 but not extend into the through holes TH1, so as to be used as the trace, but not limited thereto. In some embodiments, when there is another circuit structure formed on another side of the substrate 12 facing the conductive patterns 22b, at least another of the conductive patterns 22b may also be disposed on the second surface 12S2 of the substrate 12 but not extend into the through holes TH1 according to the requirements, but not limited thereto.

In some embodiments, the core substrate 26 may adopt any one of the electronic devices of the above embodiments, that is, when the core substrate 26 adopts the electronic device 1b of FIG. 4, the core substrate 26 may further include the insulating layer 16 located between the seed layer 14 and the conductor layer 22, as shown in FIG. 4. Alternatively, when the core substrate 26 adopts the electronic device 1a of FIG. 2, the core substrate 26 may further include the insulating layer 16, and the insulating layer 16 may have openings located outside the through holes TH1, and the conductor layer 18 may include the bridging portions 18a and the pattern portions 18b, as shown in FIG. 2. Alternatively, when the core substrate 26 adopts the electronic device 1d of FIG. 6, the core substrate 26 may further include the insulating layer 16 and the seed layer 24 disposed between the seed layer 14 and the conductor layer 22, wherein the insulating layer 16 is located between the seed layer 14 and the seed layer 24, and the seed layer 24 is located between the insulating layer 16 and the conductor layer 22 and between the conductor layer 18 and the conductor layer 22, as shown in FIG. 6.

In one embodiment, a ratio of an orifice diameter D1 of the through hole TH1 adjacent to the first surface 12S1 to an orifice diameter D2 adjacent to the second surface 12S2 may be in a range from 0.8 to 1.2, for example. In some embodiments, a difference between the orifice diameter D1 and the orifice diameter D2 may be in a range from 0.01 μm to 1 μm, for example.

In the manufacturing method of the electronic device 2 provided in this embodiment, a circuit structure 28 is formed on the core substrate 26 after the core substrate 26 is formed. The circuit structure 28 may include at least one insulating layer and at least one conductive layer CL1 to redistribute wirings and/or further increase fan-out area of the wirings, or different electronic units may be electrically connected to each other by the circuit structure 28. Alternatively, the circuit structure 28 may be a substrate used as an electrical interface routing between one circuit and another circuit. A purpose of the circuit structure is to expand wirings to have greater distance between the wirings or to redistribute the wirings to other wirings with different distance. In other words, the circuit structure 28 in the present disclosure may be a redistribution layer/structure. The circuit structure mentioned here or in the following contents may be electrically connected to each chip or each electronic unit by connecting elements or other bonding elements. The step of forming the circuit structure 28 may include thermal processes, such as deposition, oxidation, annealing, surface treatment, or other processes. In FIG. 7, the circuit structure 28 may include a plurality of insulating layers and a plurality of conductive layers CL1, wherein a combination of the insulating layers is represented by a single insulating layer IN1, but the present disclosure is not limited thereto. The uppermost conductive layer CL1 may include, for example, a plurality of pads.

Then, at least one electronic unit may be disposed on the circuit structure 28. In this embodiment, the electronic unit 30 and the electronic unit 32 may be disposed on the circuit structure 28, so that the electronic unit 30 and the electronic unit 32 may be bonded to the pads of the circuit structure 28 by bonding pads 34. The electronic unit 30 and/or the electronic unit 32 may include a chip, a chip package structure, a chip assembly structure, or other types of element structures. In the embodiment of FIG. 7, the electronic unit 30 may include a chip 30a and a circuit structure 30b, while the electronic unit 32 may include a chip, but not limited thereto. The circuit structure 30b may, for example, be disposed between the bonding pads 34 and the chip 30a and include at least one conductive layer and at least one insulating layer. The chip 30a may have an active surface and a back surface, wherein a surface of the chip with pads is for example the active surface for being bonded with the bonding pads 34. The functions of the electronic unit 30 and the electronic unit 32 may be adjusted according to the requirements. For example, the electronic unit 30 may include a control chip, such as a graphics processing unit (GPU) chip, a field programmable gate array (FPGA) chip, a central processing unit (CPU) chip, other suitable chips, or a combination thereof, while the electronic unit 32 may be a high-bandwidth memory chip, a power management IC (PMIC) or other suitable chips.

As shown in FIG. 7, after the electronic unit 30 and the electronic unit 32 are disposed, an insulating layer 36 may be formed on the core substrate 26, the circuit structure 28, the electronic unit 30, and the electronic unit 32 to protect the core substrate 26, the circuit structure 28, the electronic unit 30, and the electronic unit 32. The method of forming the insulating layer 36 may include, for example, a molding process or other suitable processes. The insulating layer 36 may include a packaging material or other suitable materials. The packaging material may include, for example, epoxy molding compound (EMC) or other suitable organic materials. Portion of the insulating layer 36 on the back surfaces of the electron unit 30 and the electronic unit 32 may be optionally further removed to facilitate heat dissipation of the electronic unit 30 and the electronic unit 32. In this case, the insulating layer 36 may surround the electronic unit 30 and the electronic unit 32, but not limited thereto. The step of removing the portion of the insulating layer 36 may include a grinding process or other suitable processes. In some embodiments, the insulating layer 36 may extend to a side surface of the circuit structure 28 to contact the core substrate 26, so as to protect the side surface of the circuit structure 28, but not limited thereto. In some embodiments, the insulating layer 36 may further extend to a side surface of the core substrate 26, but not limited thereto. In some embodiments, an upper surface of the insulating layer 36 may have a recess located between the electronic unit 30 and the electronic unit 32, but not limited thereto.

In the manufacturing method of this embodiment, between disposing the electronic unit 30 and the electronic unit 32 and forming the insulating layer 36, an adhesive layer 38 may be optionally formed between the electronic unit 30 and the circuit structure 28 and between the electronic unit 32 and the circuit structure 28 to enhance the adhesion between the electronic unit 30 and the circuit structure 28 and between the electronic unit 32 and the circuit structure 28. The adhesive layer 38 may include, for example, an underfill material or other suitable materials.

After the insulating layer 36 is formed, a plurality of bonding pads 40 may be formed under the conductive patterns 22b to form a chip packaging structure 2a. Subsequently, the conductive patterns 22b of the chip packaging structure 2a are bonded to a circuit carrier 42 by the bonding pads 40, such that the circuit carrier 42 may be electrically connected to the conductor layer 18. The circuit carrier 42 may include, for example, a circuit board or other suitable carrier elements. In the embodiment of FIG. 7, after bonding the chip package structure 2a to the circuit carrier 42, an adhesive layer 44 may be optionally formed between the core substrate 26 and the circuit carrier 42 to enhance the adhesion between the chip package structure 2a and the circuit carrier 42. The adhesive layer 44 may be identical or similar to, for example, the adhesive layer 38.

In some embodiments, as shown in FIG. 7, the substrate 12 may optionally have a pattern 12P. For example, the pattern 12P may include an alignment mark or other suitable patterns. The pattern 12P may, for example, be located in the substrate 12 and at a distance from the first surface 12S1 of approximately 40% to 60% of the thickness of the substrate 12, but not limited thereto. The pattern 12P may be formed, for example, by the laser modification process or other suitable processes, wherein the parameters or conditions of the laser modification process used to form the pattern 12P may be different from that of the laser modification process used to etch the substrate 12.

Refer to FIG. 8, which schematically illustrates a cross-sectional view of an electronic device according to a sixth embodiment of the present disclosure. As shown in FIG. 8, the electronic device 3 of this embodiment differs from the electronic device 2 of FIG. 7 in that the circuit carrier 42 may include a core substrate 46, a circuit structure 48, and a circuit structure 50, wherein the circuit structure 48 and the circuit structure 50 are respectively disposed on an upper side and a lower side of the core substrate 46. The core substrate 46 may include the substrate 52 and a plurality of conductive elements 54. The substrate 52 may include a sub-substrate 52-1 and a sub-substrate 52-2 stacked in sequence, wherein the substrate 52 may have a plurality of through holes TH2, and the through holes TH2 may be defined by sub-through holes TH21 of the sub-substrate 52-1 and the sub-through holes TH22 of the sub-substrate 52-2, and the conductive elements 54 may be respectively disposed in the corresponding through holes TH2 and penetrate through the substrate 52. In other words, the conductive element 54 may be a conductive via. In some embodiments, the conductive elements 54 may, for example, be identical or similar to the conductive vias in above contents, so they are not repeated herein. In some embodiments, the substrate 52 may include a structure having more than two sub-substrates stacked sequentially. The coefficients of thermal expansion and/or thicknesses of any two of the sub-substrates may be the same or different. For example, the coefficient of thermal expansion of the sub-substrate 52-1 may be different from that of the sub-substrate 52-2. The coefficient of thermal expansion of the sub-substrate 52-1 may be, for example, less than that of sub-substrate 52-2. The thickness of the substrate 52 may be greater than that of substrate 12, or the thickness of the core substrate 46 may be greater than that of the substrate 12, but not limited thereto. The material of the substrate 52 of this embodiment may be similar or identical to the substrate 12 of FIG. 2, so the above contents may be referenced, and it will not be repeated here. In some embodiments, the substrate 52 may include BT resin or other suitable substrate materials. In some embodiments, the core substrate 46 may provide a good supporting effect. In some embodiments, the transmittances of the substrate 52 and the substrate 12 with respect to light may be different, and for example, the transmittance of the substrate 52 with respect to white light is greater than that of the substrate 12 with respect to white light.

As shown in FIG. 8, the circuit structure 48 may include at least one conductive layer CL2 and at least one insulating layer IN2, and the circuit structure 50 may include at least one conductive layer CL3 and at least one insulating layer IN3. In this embodiment, the circuit structure 48 may include a plurality of insulating layers IN2, wherein at least one of the insulating layers IN2 may extend into the through holes TH2, and the circuit structure 50 may include a plurality of insulating layers IN3, wherein at least one of the insulating layers IN3 may extend into the through holes TH2. The insulating layer IN2 and the insulating layer IN3 extending into the through holes TH2 may have the same function as the insulating layer 16 mentioned above, and lengths of the portions of the insulating layer IN2 and the insulating layer IN3 extending into the through hole TH2 in the direction DR3 may be similar or identical to that of the portion 16P3 or the portion 16P4 of the insulating layer 16 extending into one of the through holes TH1 in the direction DR3, which will not be repeated here. The conductive layers and the insulating layers of the circuit structure 48 and the circuit structure 50 may be similar or identical to the conductive layers and the insulating layers of the circuit structure 28, so the above contents may be referenced, and they will not be repeated here. According to some embodiments, the circuit carrier 42 may not include the circuit structure 48 and/or the circuit structure 50.

In some embodiments, the core substrate 46 may further optionally include a buffer layer 56 disposed between the conductive elements 54 and the substrate 52. The buffer layer 56 may be identical or similar to buffer layer 20 in FIG. 2, so the above contents may be referenced, and it will not be repeated here.

In the embodiment of FIG. 8, the sub-substrate 52-1 of the substrate 52 of the core substrate 46 may further have a recess RE, and the electronic device 3 may further include an electronic element 58 disposed in the recess RE of the sub-substrate 52-1. An active surface of the electronic element 58 may face towards the circuit structure 48, and the electronic element 58 may be electrically connected to the circuit structure 48. Disposing the electronic element 58 in the recess RE of the sub-substrate 52-1 help shorten the signal transmission path between the electronic element 58 and the electronic unit 30 and/or the electronic unit 32. The electronic element 58 may be attached to the recess RE, for example, by an adhesive layer 60. The electronic element 58 may include, for example, a passive element or other suitable elements. The insulating layer IN2 of the circuit structure 48 may optionally be disposed in the recess RE, or the recess RE may be filled up with another insulating layer, but not limited thereto. According to some embodiments, the electronic element 58 may optionally overlap at least one of the electronic units. According to some embodiments, the electronic element 58 may not overlap the electronic units.

In some embodiments, the circuit carrier 42 may further include a solder resist layer 62 disposed under the circuit structure 50 and used to protect the insulating layers of the circuit structure 50, and the pads of the circuit structure 50 are exposed through the solder resist layer 62, but not limited thereto. The electronics 3 may further include a plurality of bonding pads 64 disposed on pads of the circuit structure 50 and used to be bonded with other elements.

In FIG. 8, the upper surface 48S of the uppermost insulating layer IN2 of the circuit structure 48 may be, for example, a rough surface and be used to improve the adhesion of the uppermost insulating layer IN2 to a heat dissipation cover. For example, a surface roughening step may be performed on portion of the upper surface 48S of the uppermost insulating layer IN2 of the circuit structure 48 adjacent to its edge. The surface roughening step may include laser, wet etching, dry etching, plasma, transfer printing, or a combination thereof. In some embodiments, the surface roughening step may further be performed on surfaces of the conductive layers CL2 and/or surfaces of the insulating layers IN2 during the progress of alternately stacking the conductive layers CL2 and the insulating layers IN2 of the circuit structure 48. In some embodiments, the electronic device 3 may further include a scattering cover bonded to the upper surface 48S, but not limited thereto.

In summary, in the manufacturing method of the electronic device of the present disclosure, since the insulating layer having the opening is formed in the through hole before forming the conductor layer, the solid conductor layer may be formed at the center of the through hole to prevent another conductor layer from being closed too early at the orifice of the through holes, thereby reducing the probability of forming voids or holes in the through holes. Accordingly, the signal transmission quality and reliability of the conductive vias may be improved. In the electronic device of the present disclosure, the grain size of the conductor layer adjacent to the center of the through hole is less than that of the conductor layer away from the center of the through hole, which helps reduce total manufacturing time of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate, wherein the substrate comprises at least one through hole;
forming a seed layer on the substrate, wherein the seed layer extends into the at least one through hole;
forming an insulating layer on the seed layer, wherein a portion of the insulating layer extends into the at least one through hole, and a portion of the seed layer in the at least one through hole is exposed; and
forming a conductor layer on the portion of the seed layer.

2. The manufacturing method of the electronic device according to claim 1, further comprising forming a buffer layer on the substrate before forming the seed layer.

3. The manufacturing method of the electronic device according to claim 1, further comprising patterning the insulating layer to expose another portion of the seed layer outside the at least one through hole of the substrate after forming the insulating layer.

4. The manufacturing method of the electronic device according to claim 3, wherein the conductor layer comprises a bridging portion and a pattern portion, the bridging portion corresponds to the portion of the seed layer, and the pattern portion corresponds to the another portion of the seed layer.

5. The manufacturing method of the electronic device according to claim 4, further comprising forming another conductor layer on the conductor layer and the insulating layer after forming the conductor layer.

6. The manufacturing method of the electronic device according to claim 1, further comprising forming another conductor layer on the conductor layer and the insulating layer after forming the conductor layer.

7. The manufacturing method of the electronic device according to claim 1, further comprising removing the insulating layer after forming the conductor layer.

8. The manufacturing method of the electronic device according to claim 7, further comprising forming another conductor layer on the seed layer and the conductor layer after removing the insulating layer.

9. The manufacturing method of the electronic device according to claim 8, further comprising performing an etching process between removing the insulating layer and forming the another conductor layer.

10. The manufacturing method of the electronic device according to claim 1, further comprising forming another seed layer on the conductor layer and the insulating layer after forming the conductor layer.

11. The manufacturing method of the electronic device according to claim 10, further comprising forming another conductor layer on the another seed layer after forming the another seed layer.

12. An electronic device, comprising:
a substrate comprising at least one through hole;
a seed layer disposed on the substrate and extending into the at least one through hole;
a conductor layer disposed on a portion of the seed layer in the at least one through hole; and
another conductor layer disposed on the seed layer and the conductor layer, wherein a grain size of the conductor layer is less than a grain size of the another conductor layer.

13. The electronic device according to claim 12, further comprising an insulating layer disposed between the seed layer and the another conductor layer, wherein the insulating layer extends into the at least one through hole, the insulating layer comprises a first opening in the at least one through hole, and the first opening exposes the portion of the seed layer.

14. The electronic device according to claim 13, wherein a distance between a center of the first opening and a surface of the insulating layer outside the at least one through hole is greater than a quarter of a thickness of the substrate and less than or equal to a half of the thickness of the substrate, and a length of a portion of the insulating layer extending into the at least one through hole is greater than or equal to 0.05 times the distance and less than or equal to 0.8 times the distance.

15. The electronic device according to claim 13, wherein the insulating layer comprises a second opening outside the at least one through hole, and the second opening exposes another portion of the seed layer.

16. The electronic device according to claim 15, wherein the conductor layer comprises a bridging portion and a pattern portion, the bridging portion corresponds to the portion of the seed layer, and the pattern portion corresponds to the another portion of the seed layer.

17. The electronic device according to claim 12, further comprising a buffer layer disposed between the substrate and the seed layer.

18. The electronic device according to claim 12, further comprising a circuit carrier electrically connected to the conductor layer, wherein the circuit carrier comprises a core substrate, and a thickness of the core substrate is greater than a thickness of the substrate.

19. The electronic device according to claim 18, wherein the core substrate comprises a first sub-substrate and a second sub-substrate stacked sequentially, and a coefficient of thermal expansion of the first sub-substrate is different from a coefficient of thermal expansion of the second sub-substrate.

20. The electronic device according to claim 19, further comprising an electronic element disposed in a recess of the first sub-substrate.
